(19) United States
(12) Patent Application Publication
(10) Pub. No.: US 2010/0148187 A1
(43) Pub. Date: Jun. 17, 2010

(54) SEMICONDUCTOR DEVICE

(75) Inventor: Hisashi Aikawa, Oita (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/634,819

(22) Filed: Dec. 10, 2009

(30) Foreign Application Priority Data
Dec. 12, 2008 (JP) 2008-316438

(51) Int. Cl. H01L 29/161

(52) U.S. Cl. 257/77; 257/E29.084

(57) ABSTRACT

A semiconductor device according to an embodiment includes a transistor including a gate electrode formed on a semiconductor substrate of a predetermined crystal via a gate insulating film and a source-drain region formed in the semiconductor substrate so as to have a convex portion in a direction of a gate width and in which an epitaxial crystal having a lattice constant different from that of the predetermined crystal is embedded, and a contact plug formed on the source-drain region other than the convex portion.

### CROSS-REFERENCE TO RELATED APPLICATIONS

This application is based upon and claims the benefit of priority from prior Japanese Patent Application No. 2008-316438, filed on Dec. 12, 2008, the entire contents of which are incorporated herein by reference.

### BACKGROUND

As a conventional technique, a design method of a semiconductor device is known that includes a semiconductor substrate, an element isolation insulation film selectively formed in the principal surface of a semiconductor substrate, a gate structure selectively formed on the principal surface of the semiconductor substrate in an element formation region specified with the element isolation insulation film, and a source drain area which is formed in the principal surface of a semiconductor substrate and accomplishes a pair across a channel forming region located at a lower part of the gate structure in the element formation region, and that can adjust stress applied to the semiconductor substrate of a portion in which the gate structure is formed according to a shape of the element formation region. This technique is disclosed in, for example, JP-A-2004-281631.

The element formation region of the semiconductor device includes an upper surface structure having a convex portion formed along the periphery thereof. Consequently, stress applied from the element separation region to the semiconductor substrate changes, using a case that the convex portion is not formed as a benchmark. Hence, stress applied to the semiconductor substrate at a part in which a gate structure is formed can be tuned finely by formation of the convex parts. As a result, a current driving ability of a Metal-Oxide-Semiconductor Field-Effect Transistor (MOSFET) having the gate structure can be set to a desired value.

### BRIEF SUMMARY

According to an embodiment of the invention, a semiconductor device is provided, the semiconductor device including a transistor including a gate electrode formed on a semiconductor substrate of a predetermined crystal via a gate insulating film and a source-drain region formed in the semiconductor substrate so as to have a convex portion in a direction of a gate width and in which an epitaxial crystal having a lattice constant different from that of the predetermined crystal is embedded, and a contact plug formed on the source-drain region other than the convex portion.

### BRIEF DESCRIPTION OF THE DRAWING

FIG. 1 is a top view schematically showing a semiconductor device according to a first Example;

FIG. 2 is a cross-sectional view taken along the line II-II in FIG. 1;

FIG. 3 is a cross-sectional view taken along the line III-III in FIG. 1;

FIG. 4 is a top view schematically showing a semiconductor device according to a second Example;

FIG. 5 is a top view schematically showing a semiconductor device according to a third Example;

FIG. 6 is a top view schematically showing a semiconductor device according to a fourth Example;

FIG. 7 is a top view schematically showing a semiconductor device according to a fifth Example;

FIG. 8 is a top view schematically showing a semiconductor device according to a sixth Example;

FIG. 9 is a top view schematically showing a semiconductor device according to a seventh Example;

FIG. 10 is a top view schematically showing a semiconductor device according to a eighth Example; and

FIG. 11 is a top view schematically showing a semiconductor device according to a ninth Example.

### DETAILED DESCRIPTION

### First Embodiment

### Structure of Semiconductor Device

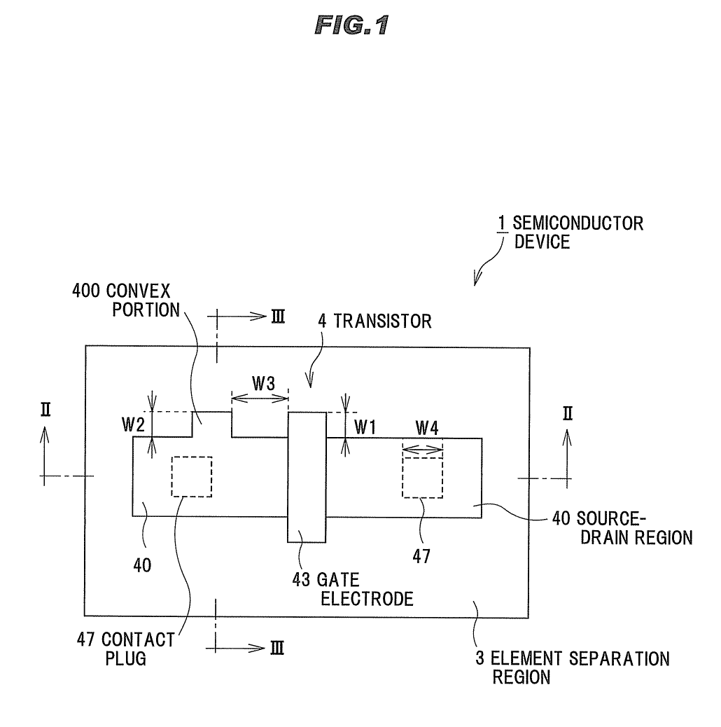

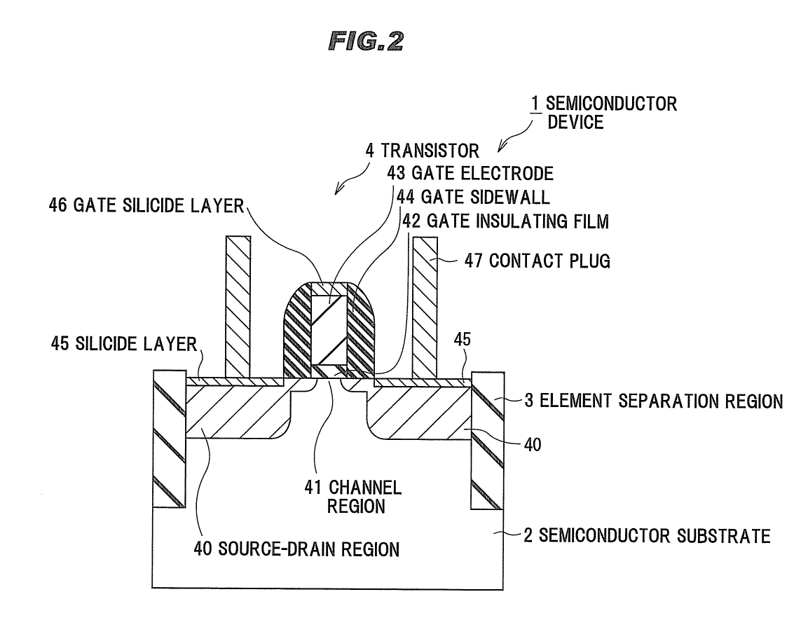

FIG. 1 is a top view schematically showing a semiconductor device according to a first Example and FIG. 2 is a cross-sectional view taken along the line II-II in FIG. 1. In FIG. 1, a gate sidewall, a gate silicide layer and a silicide layer of a transistor shown in FIG. 2 are not shown.

As shown in FIGS. 1 and 2, the semiconductor device 1 roughly includes a semiconductor substrate 2, an element separation region 3 formed on the semiconductor substrate 2, and a transistor 4 formed on the semiconductor substrate 2.

The semiconductor substrate 2 is formed of a Si based crystal (a predetermined crystal) including Si as a main component such as Si crystal and SiGe crystal. Hereinafter, the semiconductor substrate 2 used in each embodiment including the embodiment will be formed of the Si crystal.

The element separation region 3 has a Shallow Trench Isolation (STI) structure, and the element separation region 3 is obtained by embedding an insulating film in a groove having a predetermined pattern formed on the semiconductor substrate 2. The insulating film can be formed of a SiO₂ film, as an example.

As shown in FIG. 2, the transistor 4 roughly includes a source-drain region 40 formed in the semiconductor substrate 2, a channel region 41 formed below a gate electrode 43, the gate electrode 43 formed on the semiconductor substrate 2 via a gate insulating film, a gate sidewall 44 formed on a side surface of the gate electrode 43, a silicide layer 45 formed on an upper surface of the source-drain region 40, a gate silicide layer 46 formed on an upper surface of the gate electrode 43, and a contact plug 47 electrically connecting the source-drain region 40 and upper wires or the like via the silicide layer 45. The contact plug 47 shown with a dotted line on a top view in each of the following embodiments has a shape obtained when the contact plug 47 shown in FIG. 2 is projected on the source-drain region 40 from a perpendicular and upper direction.

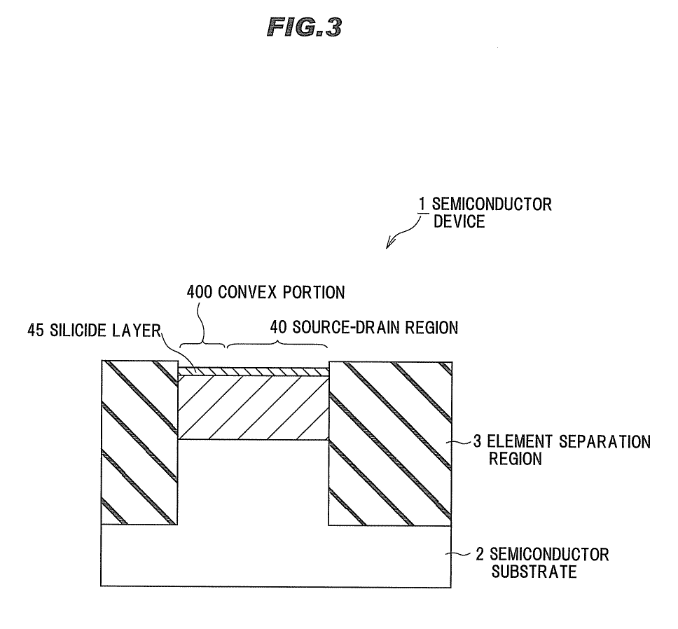

FIG. 3 is a cross-sectional view taken along the line III-III in FIG. 1. As shown in FIGS. 1 and 3, the source-drain region 40 has a convex portion 400 formed so as to project in a gate width direction. The same epitaxial crystal that is embedded in the source-drain region 40 is embedded in the convex portion 400.

The source-drain region 40 has an epitaxial crystal embedded therein and having a lattice constant different from that of a Si crystal of the semiconductor substrate 2, lattice distortion occurs due to the difference of the lattice constant, and according to variation in size of the lattice constant of the epitaxial crystal to the lattice constant of the Si crystal, compression or tensile strain in a channel direction occurs. In case of the source-drain region 40 in which the convex portion 400 is formed, contact portion between the Si crystal and the epitaxial crystal is increased in comparison with the source-drain region in which the convex portion 400 is not formed, and a region where the lattice distortion occurs is increased, so that the larger compression or tensile strain in the channel direction can be generated in the channel region 41.

Here, the convex portion 400 is not formed for preventing poor connection due to deviation of positioning at the formation of the contact plug 47, but it is formed in the source-drain region 40 for generating distortion in the channel region 41, consequently, the contact plug 47 is not connected to the convex portion 400. Namely, the convex portion 400 is not used as a pathway of source-drain current.

The source-drain region 40 has an embedded epitaxial crystal which is different according to combination of a channel direction of the channel region 41 and conductivity type of the transistor 4. For example, when the channel direction is <110>, if the conductivity type of the transistor 4 is N-type, tensile strain is generated in a channel direction, so that mobility of carrier of the transistor 4 is improved, and if the conductivity type of the transistor 4 is P-type, compression strain is generated in the channel direction, so that the mobility of the carrier of the transistor 4 is improved.

Also, for example, when the channel direction is <100>, regardless of the conductivity type, the tensile strain is generated in the channel direction, so that the mobility of the carrier of the transistor 4 is improved. Further, <110> shows [110] and a direction equivalent to [110]. Also, <100> shows [100] and a direction equivalent to [100].

When the tensile strain in the channel direction is generated in the channel region 41, the epitaxial crystal having the lattice constant smaller than a Si crystal constituting the semiconductor substrate 2, for example, SiC crystal or the like is embedded in the source-drain region 40. Also, when the compression strain in the channel direction is generated in the channel region 41, the epitaxial crystal having the lattice constant larger than the Si crystal constituting the semiconductor substrate 2, for example, SiGe crystal or the like is embedded in the source-drain region 40.

Also, for example, when the semiconductor substrate 2 is formed of the SiGe crystal of Si based crystal and the tensile strain in the channel direction is generated in the channel region 41, the epitaxial crystal having the lattice constant smaller than the SiGe crystal constituting the semiconductor substrate 2, for example, SiC crystal or the like is embedded in the source-drain region 40. Also, when the compression strain in the channel direction is generated in the channel region 41, the epitaxial crystal having the lattice constant larger than a SiGe crystal constituting the semiconductor substrate 2, for example, a SiGe crystal or the like having higher Ge content than the SiGe crystal constituting the semiconductor substrate 2 is embedded in the source-drain region 40.

The gate insulating film 42 is formed of, as an example, SiO₂, SiN, SiON or high dielectric material (for example, Hf based material such as HfSiON, HfSiO, HfO, Zr based material such as ZrSiON, ZrSiO, ZrO, Y based material such as Y₂O₃).

The gate electrode 43 is formed of, as an example, a polycrystalline Si or a polycrystalline SiGe containing a conductivity type impurity, when the conductivity type of the transistor 4 is N-type, a N-type impurity ion such as As ion, P ion or the like is implanted as the conductivity type impurity, and when the conductivity type of the transistor 4 is P-type, a P-type impurity ion such as B ion, BF₂ ion or the like is implanted as the conductivity type impurity. Further, the gate electrode 43 can be a metal gate electrode formed of W, Ta, Ti, Hf, Zr, Ru, Pt, Ir, Mo, Al or compounds thereof.

The gate sidewall 44 is formed of an insulating material such as SiN. Also, the gate sidewall 44 can have a two-layer structure or a multilayer structure of not less than 3 layers formed of a plurality of insulating materials such as SiN, SiO₂, TEOS (Tetraethoxysilane).

The silicide layer 45 and the gate silicide layer 46 is formed of, as an example, a compound of Si and a metal such as Ni, Pt, Co, Er, Y, Yb, Ti, Pb, NiPt, CoNi. Further, the gate silicide layer 46 is formed by changing an upper part of the gate electrode 43 into silicide, and a full silicide gate electrode formed by changing the whole of the gate electrode 43 into silicide can be also used.

The contact plug 47 is formed of a metal material having low electric resistivity such as W, Ir, Pt.

As shown in FIG. 1, a distance W1 means a distance from a side part of the source-drain region 40 in the gate width direction to an end part of the gate electrode 43. The distance W1 is set from a design rule and process margin of the semiconductor device 1. Here, the design rule means a rule that prescribes a planar dimension and mutual position relation of semiconductor elements (for example, transistors), a stereoscopic position relation between the semiconductor elements, a distance between the element separation regions and the like, which are determined based on the minimum dimension of the semiconductor device. Also, the process margin means a margin of the process in consideration of dimensional variability which occurs in a fabrication process of the semiconductor device, and it is set so that the fabricated semiconductor device is grouped into a category of good item even if quality of the semiconductor device to be fabricated varies due to variation of characteristics of the fabrication process.

As shown in FIG. 1, the width W2 means a width of the convex portion 400 in the gate width direction. The width W2 is set so as not to hinder integration of the transistor, and as an example, it is set to not more than the distance W1. Further, the width W2 can be larger than the distance W1 if it has a size that does not hinder the integration of the transistor.

As shown in FIG. 1, a distance W3 means a distance between the gate electrode 43 and the convex portion 400. The width W3 is set from a design rule and process margin of the semiconductor device 1. The semiconductor device 1 has the distance W3 as a distance between the gate electrode 43 and the convex portion 400, so that the convex portion 400 is not formed just below the gate electrode 43.

The width W4 means the maximum width of the contact plug 47 projected on the source-drain region 40. The contact plug 47 has a square-shaped or circular-shaped cross-section, so that the width W4 shows a length of a side or a diameter of the contact plug 47.

### Advantages of First Embodiment

According to the semiconductor device 1 of the first embodiment, the source-drain region 40 in which the convex portion 400 is formed can generate the larger compression or tensile strain in the channel region 41 than the source-drain region in which the convex portion 400 is not formed, and the current driving ability of the transistor 4 can be enhanced.

Also, the semiconductor device 1 has the distance W1 of a distance from a side part of the source-drain region 40 in the gate width direction to an end part of the gate electrode 43 and the width W2 of a width of the convex portion 400 in the gate width direction which are set to have almost the same length respectively, so that the driving ability of the transistor can be enhanced without a hindrance of the integration of the transistor 4.

Further, the source-drain region 40 has an embedded epitaxial crystal which is selected based on combination of a channel direction of the channel region 41 and conductivity type of the transistor 4, so that compression or tensile strain having a desired largeness can be generated in the channel region 41 and the current driving ability of the transistor can be enhanced regardless of the conductivity type.

Since the convex portion 400 is not used as a pathway of source-drain current, it does not have to be connected by the contact plug 47, the shape and location thereof is freely determined insofar as the condition between the width W2 and the distance W3 is satisfied, and compression or tensile strain having a desired largeness can be generated in the channel region 41.

### Second Embodiment

### Structure of Semiconductor Device

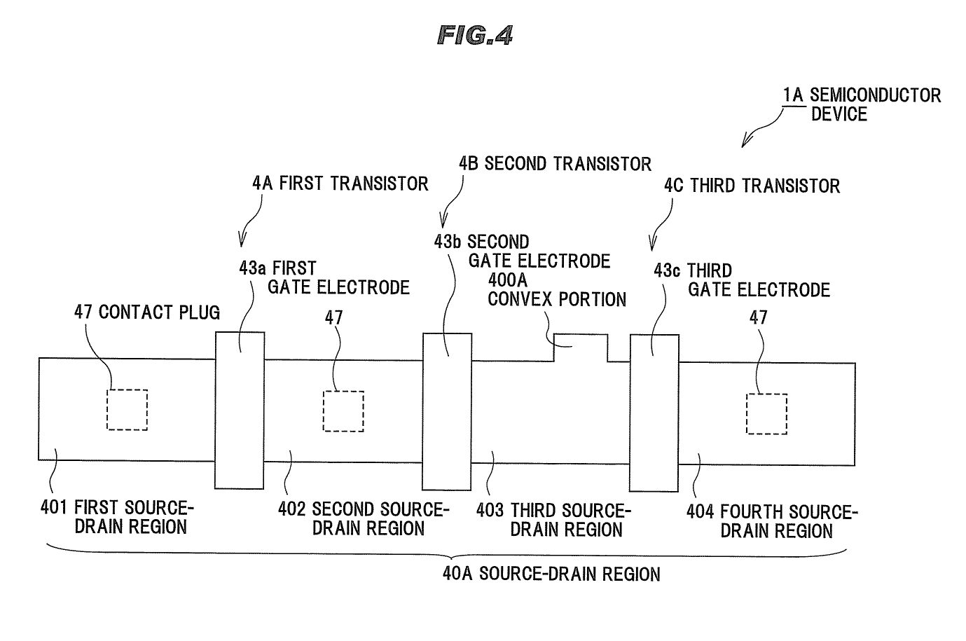

FIG. 4 is a top view schematically showing a semiconductor device according to a second Example. In a top view of each of the following embodiments, an element separation region, a gate sidewall, a gate silicide layer and a silicide layer are not shown. Also, in each of the following embodiments, different points from the first embodiment will be mainly explained. Further, in each of the following embodiments, with regard to elements having the same construction and function as the first embodiment, for the sake of simplifocation, the same references as those of the first embodiment will be used, and detail explanation will be omitted.

As shown in FIG. 4, the semiconductor device 1A, as an example, roughly includes first to third transistors 4A to 4C having the same conductivity type.

The first transistor 4A has a first gate electrode 43a, the second transistor 4B has a second gate electrode 43b, and the third transistor 4C has a third gate electrode 43c. The first to third gate electrodes 43a to 43c are formed on a source-drain region 40A via a gate insulating film.

Also, as shown in FIG. 4, the source-drain region 40A is separated into four areas of first to fourth source-drain regions 401 to 404 bounded by the first to third gate electrodes 43a to 43c.

The first source-drain region 401 belongs to the first transistor 4A, the second source-drain region 402 belongs to the first and second transistors 4A and 4B, the third source-drain region 403 belongs to the second and third transistors 4B and 4C, and the fourth source-drain region 404 belongs to the third transistors 4C.

The semiconductor device 1A, as an example, the third source-drain region 403 has a convex portion 400A formed so as to project from a side part in a gate width direction. The third source-drain region 403 does not have the contact plug 47 to be connected thereto and the convex portion 400 is not formed so as to be connected by the contact plug 47, so that the shape and location thereof is freely determined insofar as the condition between the width W2 and the distance W3 in the first embodiment is satisfied. Consequently, the third source-drain region 403 in which the convex portion 400A is formed can generate compression or tensile strain having a desired largeness in the channel regions of the second and third transistors 4B, 4C.

An epitaxial crystal is embedded in the source-drain region 40A in which the convex portion 400A is formed according to the channel directions and conductivity types of the first to third transistors 4A to 4C, similarly to the first embodiment.

### Advantages of Second Embodiment

According to the semiconductor device 1A of the second embodiment, the third source-drain region 403 in which the convex portion 400A is formed can generate the larger compression or tensile strain in the channel regions of the second and third transistors 4B, 4C than the source-drain region in which the convex portion 400A is not formed, and the current driving ability of the second and third transistors 4B, 4C can be enhanced. Also, the contact plug 47 is not connected to the third source-drain region 403 in which the convex portion 400A is formed, so that the shape and location of the convex portion 400A is freely determined insofar as the condition between the width W2 and the distance W3 is satisfied.

### Third Embodiment

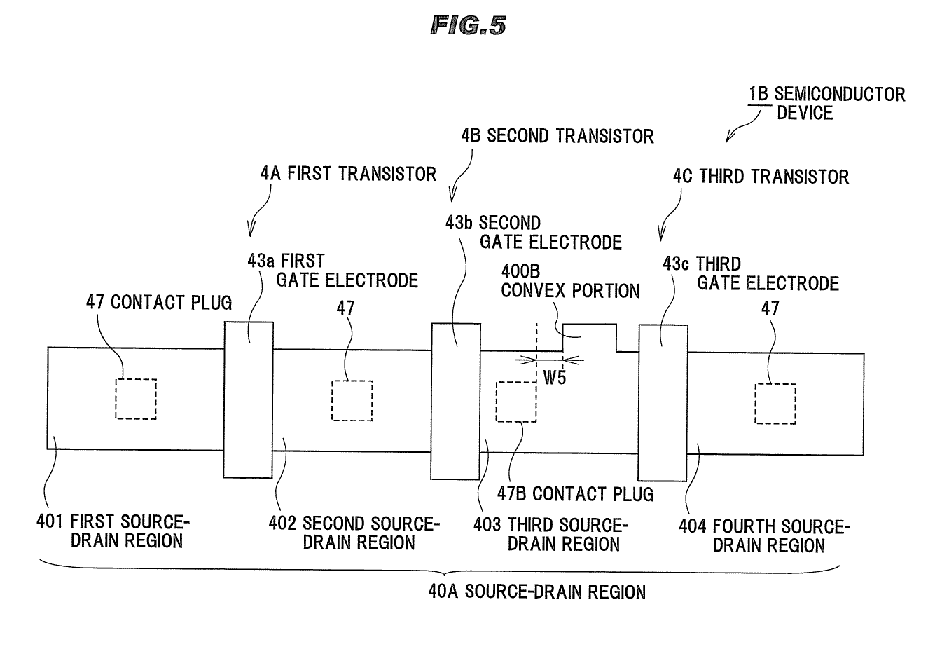

FIG. 5 is a top view schematically showing a semiconductor device according to a third Example. A semiconductor device 1B, as an example, a third source-drain region 403 has a convex portion 400B formed so as to project from a side part in a gate width direction. Also, the semiconductor device 1B has a structure that a contact plug 47B is electrically connected to the third source-drain region 403 via a suicide layer.

As shown in FIG. 5, a distance W5 means a distance between an extended line of a side of the contact plug 47B projected on the third source-drain region 403 and an extended line of a side of the convex portion 400B which are mutually located at nearest position, and the extended line of the convex portion 400B is set so as to be always located outside the contact plug 47 which is shown with a dotted line. Consequently, it becomes clear that the convex portion 400B is not formed for preventing poor connection due to deviation of positioning at the formation of the contact plug 47B, but it is formed in the third source-drain region 403 for generating distortion in the channel region.

Also, the convex portion 400B is not formed so as to be connected by the contact plug 47B, so that the shape and location of the convex portion 400B is freely determined insofar as the conditions of the width W2 and the distance W3 in the first embodiment and the W5 in the embodiment are satisfied. Consequently, the third source-drain region 403 in which the convex portion 400B is formed can generate compression or tensile strain having a desired largeness in the channel regions of the second and third transistors 4B, 4C.

An epitaxial crystal is embedded in the source-drain region 40A in which the convex portion 400B is formed according to the channel directions and conductivity types of the first to third transistors 4A to 4C, similarly to the first embodiment.

### Advantages of Third Embodiment

According to the semiconductor device 1B of the third embodiment, the third source-drain region 403 in which the convex portion 400B is formed can generate the larger compression or tensile strain in the channel regions of the second and third transistors 4B, 4C than the source-drain region in which the convex portion 400B is not formed, so that the current driving ability of the second and third transistors 4B, 4C can be enhanced. Also, the convex portion 400B is not formed for preventing poor connection due to deviation of positioning at the formation of the contact plug 47 and is not formed for being connected by the contact plug 47, so that the shape and location of the convex portion 400A is freely determined insofar as the above-mentioned conditions of the width W2, the distance W3 and the W5 are satisfied.

### Fourth Embodiment

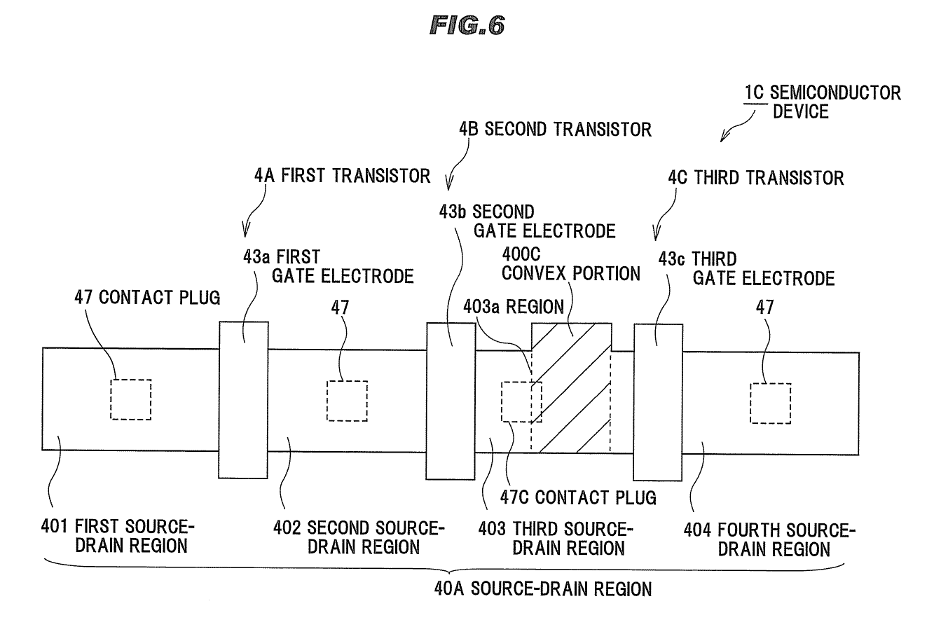

FIG. 6 is a top view schematically showing a semiconductor device according to a fourth Example. A semiconductor device 1C, as an example, a third source-drain region 403 has a convex portion 400C formed so as to project from a side part in a gate width direction. Also, the semiconductor device 1C has a structure that a contact plug 47C is electrically connected to the third source-drain region 403 via a suicide layer.

A region 403a shown with a diagonal line in FIG. 6 represents a region including the convex portion 400C, and an area between the convex portion 400C and a side of the third source-drain region 403 opposite to the convex portion 400C.

The convex portion 400C is formed at a location that the contact plug 47C projected on the third source-drain region 403 is not entirely included in the region 403a. In other words, the convex portion 400C is formed at a location that the contact plug 47C is not entirely included in the region 403a. Consequently, it becomes clear that the convex portion 400C is not formed for preventing poor connection due to deviation of positioning at the formation of the contact plug 47C, but it is formed in the third source-drain region 403 for generating distortion in the channel region.

Also, the convex portion 400C is not formed for being connected by the contact plug 47, so that the shape and location of the convex portion 400C is freely determined insofar as the conditions of the width W2 and the distance W3 in the first embodiment and the condition that the projection image of the contact plug 47C is not entirely included in the region 403a in the embodiment are satisfied. Consequently, the third source-drain region 403 in which the convex portion 400C is formed can generate compression or tensile strain having a desired largeness in the channel regions of the first and second transistors 4B, 4C.

An epitaxial crystal is embedded in the source-drain region 40A in which the convex portion 400C is formed according to the channel directions and conductivity types of the first to third transistors 4A to 4C, similarly to the first embodiment.

### Advantages of Fourth Embodiment

According to the semiconductor device 10 of the fourth embodiment, the third source-drain region 403 in which the convex portion 40013 is formed can generate the larger compression or tensile strain in the channel regions of the second and third transistors 4B, 4C than the source-drain region in which the convex portion 400C is not formed, so that the current driving ability of the second and third transistors 4B, 4C can be enhanced. Also, the convex portion 400C is not formed for being connected by the contact plug 47C, so that the shape and location of the convex portion 400C is freely determined insofar as the above-mentioned conditions of the width W2 and the distance W3 and the condition that the projection image of the contact plug 47C is not entirely included in the region 403a in the embodiment are satisfied.

### Fifth Embodiment

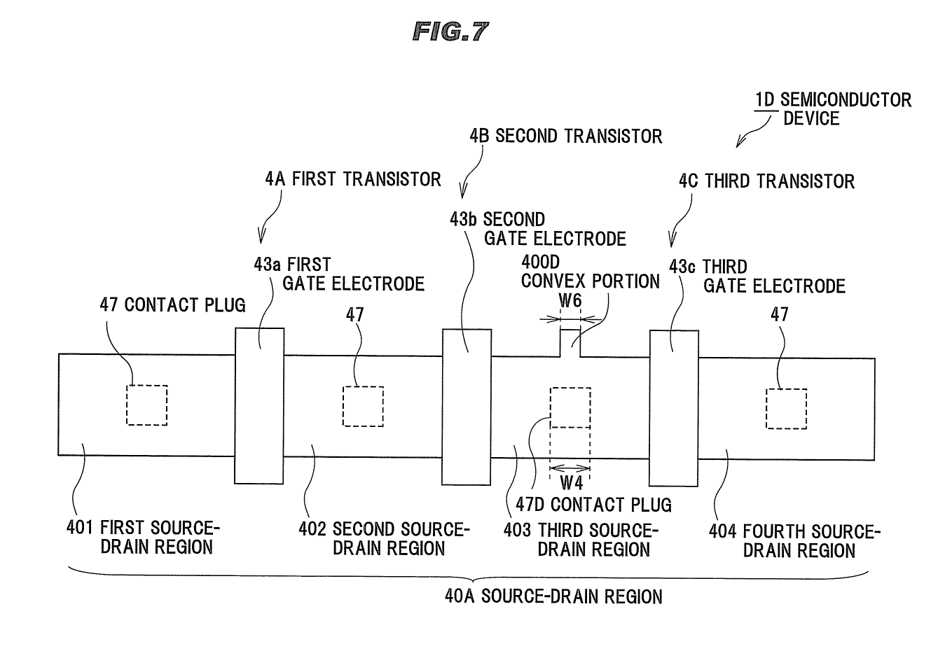

FIG. 7 is a top view schematically showing a semiconductor device according to a fifth Example. A semiconductor device 1D, as an example, a third source-drain region 403 has a convex portion 400D formed so as to project from a side part in a gate width direction. Also, the semiconductor device 1D has a structure that a contact plug 47D is electrically connected to the third source-drain region 403 via a suicide layer.

The convex portion 400D has a width W6 as a side in a gate length direction. The width W6 is smaller than a width W4 of a side of the contact plug 47D projected on the third source-drain region 403. Consequently, it becomes clear that the convex portion 400D is not formed for preventing poor connection due to deviation of positioning at the formation of the contact plug 47D, but it is formed in the third source-drain region 403 for generating distortion in the channel region.

Also, the convex portion 400D is not formed for being connected by the contact plug 47D, so that the shape and location of the convex portion 400D is freely determined insofar as the conditions of the width W2 and the distance W3 in the first embodiment and the condition of the width W6 of the convex portion 400D in the embodiment are satisfied. Consequently, the third source-drain region 403 in which the convex portion 400D is formed can generate compression or tensile strain having a desired largeness in the channel regions of the first and second transistors 4B, 4C.

An epitaxial crystal is embedded in the source-drain region 40A in which the convex portion 400D is formed according to the channel directions and conductivity types of the first to third transistors 4A to 4C, similarly to the first embodiment.

### Advantages of Fifth Embodiment

According to the semiconductor device 1D of the fifth embodiment, the third source-drain region 403 in which the convex portion 400D is formed can generate the larger compression or tensile strain in the channel regions of the second and third transistors 4B, 4C than the source-drain region in which the convex portion 400D is not formed, so that the current driving ability of the second and third transistors 4B, 4C can be enhanced. Also, the convex portion 400D has an area smaller than a cross-sectional area of the contact plug 47D connected to the third source-drain region 403, consequently, the convex portion 400D is not formed for preventing poor connection due to deviation of positioning at the formation of the contact plug 47D and not formed for being connected by the contact plug 47D, so that the shape and location of the convex portion 400D is freely determined insofar as the above-mentioned conditions of the width W2 and the distance W3 and the condition of the distance W6 of the convex portion 400D in the embodiment are satisfied.

### Sixth Embodiment

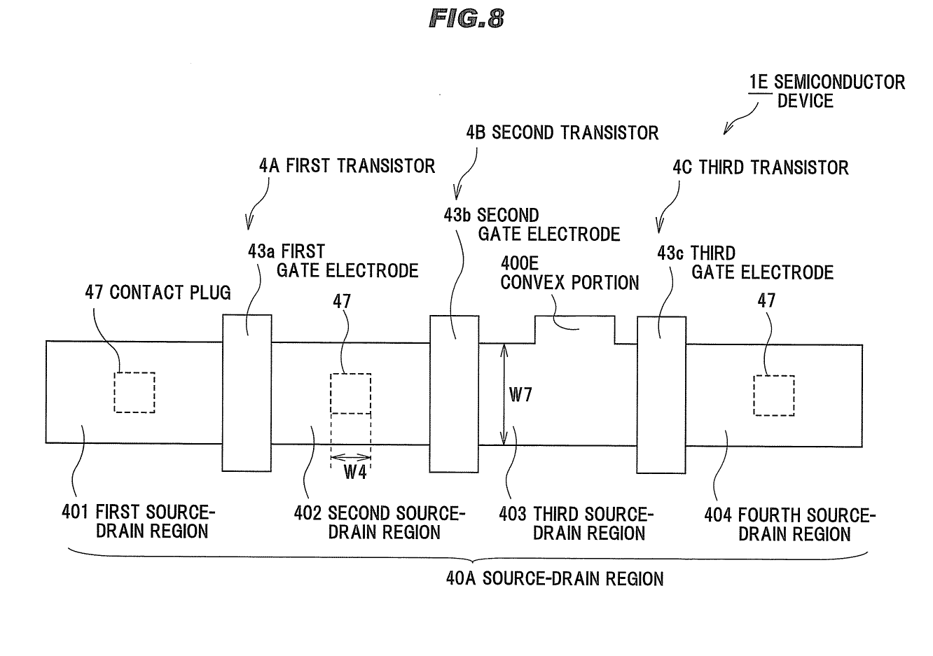

FIG. 8 is a top view schematically showing a semiconductor device according to a sixth Example. A semiconductor device 1E, as an example, a third source-drain region 403 has a convex portion 400E formed so as to project from a side part in a gate width direction.

The source-drain region 40A of the semiconductor device 1E has a width W7 in the gate width direction, and the width W7, as an example, is set to not less than twice as much as the width W4 of the contact plug 47. Namely, the contact plug 47 is not formed although it could be adequately formed in the upper part of the third source-drain region 403, therefore, the convex portion 400E is not formed for being connected by the contact plug 47, so that the shape and location of the convex portion 400E is freely determined insofar as the above-mentioned conditions of the width W2 and the distance W3 in the first embodiment are satisfied. Consequently, the third source-drain region 403 in which the convex portion 400E is formed can generate compression or tensile strain having a desired largeness in the channel regions of the first and second transistors 4B, 4C.

An epitaxial crystal is embedded in the source-drain region 40A in which the convex portion 400E is formed according to the channel directions and conductivity types of the first to third transistors 4A to 4C, similarly to the first embodiment.

### Advantages of Sixth Embodiment

According to the semiconductor device 1E of the sixth embodiment, the third source-drain region 403 in which the convex portion 400E is formed can generate the larger compression or tensile strain in the channel regions of the second and third transistors 4B, 4C than the source-drain region in which the convex portion 400E is not formed, so that the current driving ability of the second and third transistors 4B, 4C can be enhanced. Also, the convex portion 400E is not used for being connected by the contact plug 47, so that the shape and location of the convex portion 400D is freely determined insofar as the above-mentioned conditions of the width W2 and the distance W3 are satisfied.

### Seventh Embodiment

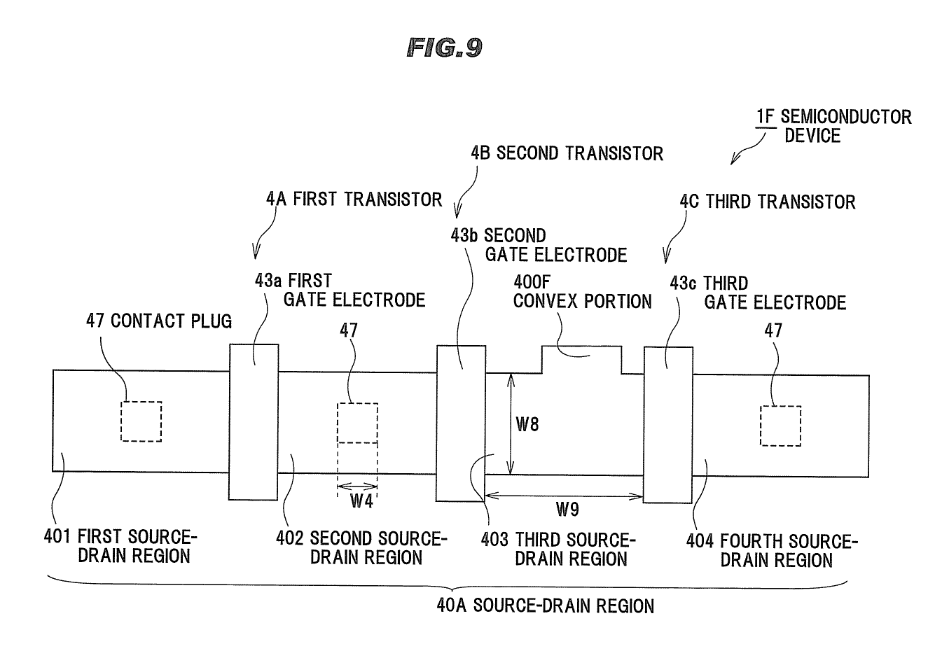

FIG. 9 is a top view schematically showing a semiconductor device according to a seventh Example. A semiconductor device 1F, as an example, a third source-drain region 403 has a convex portion 400F formed so as to project from a side part in a gate width direction.

The source-drain region 40A has a width W8, and a distance W9 means a distance between the second gate electrode 43b and the third gate electrode 43c. The width W8 and the distance W9, as an example, are set to not less than twice as much as the width W4 of the contact plug 47. Namely, the contact plug 47 is not formed although it could be adequately formed in the upper part of the third source-drain region 403, therefore, the convex portion 400E is not formed for being connected by the contact plug 47, so that the shape and location of the convex portion 400E is freely determined insofar as the above-mentioned conditions of the width W2 and the distance W3 in the first embodiment are satisfied. Consequently, the third source-drain region 403 in which the convex portion 400E is formed can generate compression or tensile strain having a desired largeness in the channel regions of the first and second transistors 4B, 4C.

An epitaxial crystal is embedded in the source-drain region 40A in which the convex portion 400F is formed according to the channel directions and conductivity types of the first to third transistors 4A to 4C, similarly to the first embodiment.

### Advantages of Seventh Embodiment

According to the semiconductor device 1F of the seventh embodiment, the third source-drain region 403 in which the convex portion 400F is formed can generate the larger compression or tensile strain in the channel regions of the second and third transistors 4B, 4C than the source-drain region in which the convex portion 400F is not formed, so that the current driving ability of the second and third transistors 4B, 4C can be enhanced. Also, the convex portion 400E is not used for being connected by the contact plug 47, so that the shape and location of the convex portion 400D is freely determined insofar as the above-mentioned conditions of the width W2 and the distance W3 are satisfied.

### Eighth Embodiment

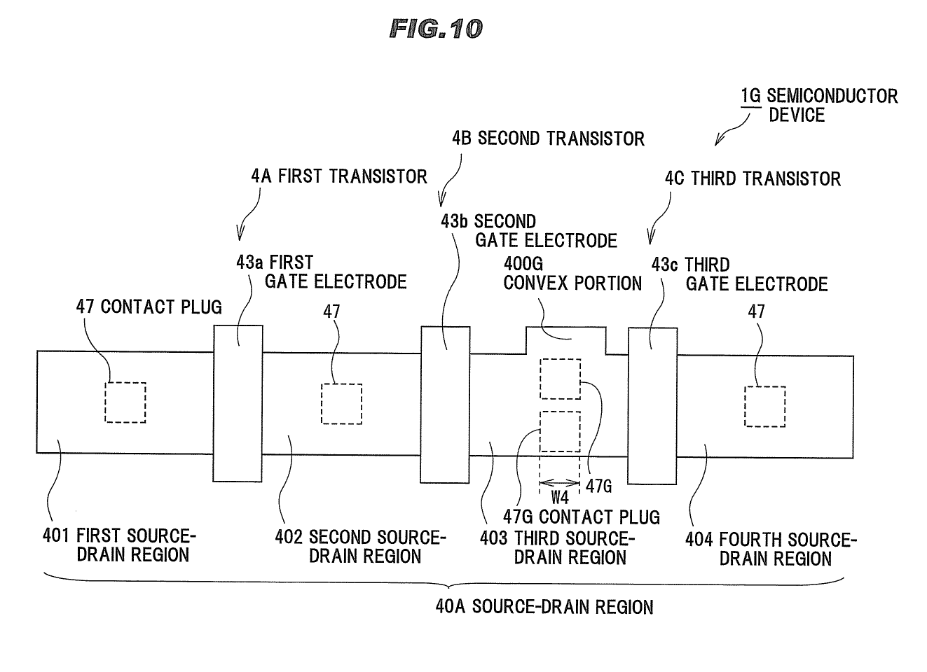

FIG. 10 is a top view schematically showing a semiconductor device according to a eighth Example. A semiconductor device 1G, as an example, a third source-drain region 403 has a convex portion 400G formed so as to project from a side part in a gate width direction.

The third source-drain region 403 has two contact plugs 47G formed in the upper part. Also, the source-drain region 40A has a width W8, and a distance W9 means a distance between the second gate electrode 43b and the third gate electrode 43c, similarly to the seventh embodiment. The width W8 and the distance W9, as an example, are set to not less than twice as much as the width W4 of the contact plugs 47G. Namely, the contact plugs 47G are not formed although they could be adequately formed in the upper part of the convex portion 400G, therefore, the convex portion 400G is not formed for being connected by the contact plugs 47G, so that the shape and location of the convex portion 400G is freely determined insofar as the above-mentioned conditions of the width W2 and the distance W3 in the first embodiment are satisfied. Consequently, the third source-drain region 403 in which the convex portion 400G is formed can generate compression or tensile strain having a desired largeness in the channel regions of the first and second transistors 4B, 4C.

An epitaxial crystal is embedded in the source-drain region 40A in which the convex portion 400G is formed according to the channel directions and conductivity types of the first to third transistors 4A to 4C, similarly to the first embodiment.

### Advantages of Eighth Embodiment

According to the semiconductor device 1G of the eighth embodiment, the third source-drain region 403 in which the convex portion 400G is formed can generate the larger compression or tensile strain in the channel regions of the second and third transistors 4B, 4C than the source-drain region in which the convex portion 400G is not formed, so that the current driving ability of the second and third transistors 4B, 4C can be enhanced.

### Ninth Embodiment

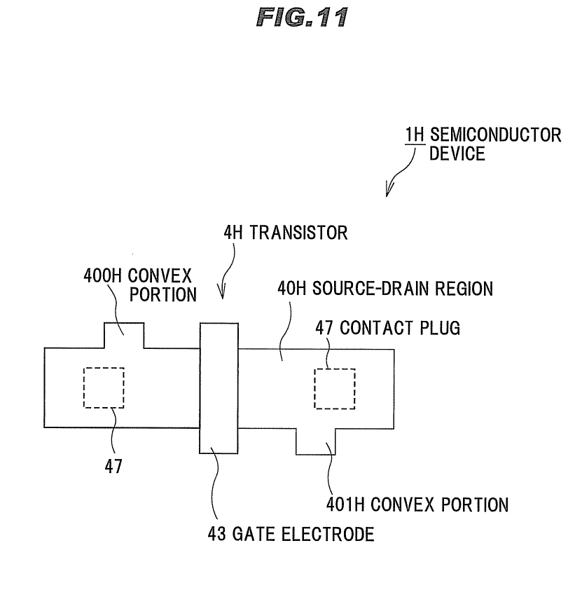

FIG. 11 is a top view schematically showing a semiconductor device according to a ninth Example. In the above-mentioned embodiments, the semiconductor devices which have one convex portion in the source-drain region have been explained, but in the embodiment, a semiconductor device which has a plurality of convex portions will be explained.

As shown in FIG. 11, a semiconductor device 1H has a transistor 4H, and the transistor 4H has a source-drain region 40H and a gate electrode 43.

In the source-drain region 40H, a convex portion 400H and a convex portion 401H are formed oppositely across the gate electrode 43.

The convex portion 400H is formed so as to project from a side part in a gate width direction of the source-drain region 40H and the convex portion 401H is formed so as to project from a side part in a gate width direction of the source-drain region 40H in an opposite direction to the convex portion 400H.

An epitaxial crystal is embedded in the source-drain region 40A in which the convex portions 400H, 401H are formed according to the channel direction and conductivity type of the transistor 4H, similarly to the first embodiment.

### Advantages of Ninth Embodiment

According to the semiconductor device 1H of the ninth embodiment, the source-drain region 40H in which the convex portions 400H, 401H are formed can generate the larger compression or tensile strain in the channel region of the transistors 4H than the source-drain region in which the convex portions 400H, 401H are not formed, so that the current driving ability of the transistor 4H can be enhanced. Also, the semiconductor device 1H has the convex portions 400H, 401H formed in both sides of the source-drain region 40H across the gate electrode 43, and compression or tensile strain is generated from the both side across the gate electrode 43, so that the current driving ability of the transistor 4H can be enhanced in comparison with a case that the convex portion is formed in one side of the source-drain region 40H.

### Other Embodiments

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

For example, in the first to eighth embodiments, one convex portion is formed in each source-drain region, but not limited to this, a plurality of the convex portions can be formed in each source-drain region, also, as shown in the ninth embodiment, the convex portions are formed in opposite sides of the source-drain region, but not limited to this, a plurality of the convex portions can be formed in the same side of the source-drain region. Further, the convex portion can be formed in the source-drain region in a state of combining the above-mentioned embodiments.

What is claimed is:

1. A semiconductor device, comprising:
a transistor comprising a gate electrode formed on a semiconductor substrate of a predetermined crystal via a gate insulating film, and a source-drain region formed in the semiconductor substrate so as to have a convex portion in a direction of a gate width, and in which an epitaxial crystal having a lattice constant different from that of the predetermined crystal is embedded; and
a contact plug formed on the source-drain region other than the convex portion.

2. The semiconductor device according to claim 1, wherein:
the transistor is a N-type one;
the semiconductor substrate has a channel direction of the <110> direction; and
the source-drain region has the epitaxial crystal embedded therein that has the lattice constant smaller than the predetermined crystal.

3. The semiconductor device according to claim 2, wherein:
the convex portion is formed at a location that the whole of contact plug is not entirely included in a region of the convex portion and a region between the convex portion and a side of the source-drain region opposite to the convex portion.

4. The semiconductor device according to claim 3, wherein:
the convex portion is not formed just below the gate electrode.

5. The semiconductor device according to claim 4, wherein:
the convex portion is formed so as to have a width of a gate length direction which is smaller than that of the contact plug.

6. The semiconductor device according to claim 5, wherein:
the convex portion is formed in at least one area of a plurality of areas separated with the gate electrodes to which the contact plug is not connected.

7. The semiconductor device according to claim 6, wherein:
the epitaxial crystal having the lattice constant smaller than the predetermined crystal is a SiC crystal.

8. The semiconductor device according to claim 1, wherein:
the transistor is a P-type one;
the semiconductor substrate has a channel direction of the <110> direction; and
the source-drain region has the epitaxial crystal embedded therein that has the lattice constant larger than the predetermined crystal.

9. The semiconductor device according to claim 8, wherein:
the convex portion is formed at a location that the whole of contact plug is not entirely included in a region of the convex portion and a region between the convex portion and a side of the source-drain region opposite to the convex portion.

10. The semiconductor device according to claim 9, wherein:
the convex portion is not formed just below the gate electrode.

11. The semiconductor device according to claim 10, wherein:
the convex portion is formed so as to have a width of a gate length direction which is smaller than that of the contact plug.

12. The semiconductor device according to claim 11, wherein:
the convex portion is formed in at least one area of a plurality of areas separated with the gate electrodes to which the contact plug is not connected.

13. The semiconductor device according to claim 12, wherein:
the epitaxial crystal having the lattice constant larger than the predetermined crystal is a SiGe crystal.

14. The semiconductor device according to claim 1, wherein:
the semiconductor substrate has a channel direction of the <110> direction; and
the source-drain region has the epitaxial crystal embedded therein that has the lattice constant smaller than the predetermined crystal.

15. The semiconductor device according to claim 14, wherein:
the convex portion is formed at a location that the whole of contact plug is not entirely included in a region of the convex portion and a region between the convex portion and a side of the source-drain region opposite to the convex portion.

16. The semiconductor device according to claim 15, wherein:
the convex portion is not formed just below the gate electrode.

17. The semiconductor device according to claim 16, wherein:
the convex portion is formed so as to have a width of a gate length direction which is smaller than that of the contact plug.

18. The semiconductor device according to claim 17, wherein:
the convex portion is formed in at least one area of a plurality of areas separated with the gate electrodes to which the contact plug is not connected.

19. The semiconductor device according to claim 18, wherein:
the epitaxial crystal having the lattice constant smaller than the predetermined crystal is a SiC crystal.

20. The semiconductor device according to claim 19, wherein:
the semiconductor substrate is formed of a Si based crystal.
